(19) United States
(12) Patent Application Publication
(10) Pub. No.: US 2016/0189923 A1
(43) Pub. Date: Jun. 30, 2016

(54) APPARATUS AND METHOD

(71) Applicant: SWINBURNE UNIVERSITY OF TECHNOLOGY, Hawthorn, Melbourne, Victoria (AU)

(72) Inventors: Saulius JUODKAZIS, Hawthorn, Melbourne (AU); Gediminas GERVINSKAS, Hawthorn, Melbourne (AU); Gediminas SENIUTINAS, Hawthorn, Melbourne (AU)

(21) Appl. No.: 14/911,570

(22) PCT Filed: Aug. 8, 2014
(86) PCT No.: PCT/AU2014/050175

§ 371 Date: Feb. 11, 2016

(30) Foreign Application Priority Data
Aug. 15, 2013 (AU) 2013903073

(51) Int. Cl. H01J 37/26; H01J 37/30; H01J 37/28

(52) U.S. Cl. CPC H01J 37/265; H01J 37/263; H01J 37/28; H01J 37/3002; H01J 2237/004; H01J 2237/28

(57) ABSTRACT

An apparatus for imaging or fabrication using charged particles, the apparatus including: a charged particle source configured to generate a charged particle beam of ions or electrons; a sample holder mounted relative to the charged particle source to hold a sample in the charged particle beam for the imaging or fabrication; and an optical source system configured to generate an optical beam, wherein the optical source system is mounted relative to the sample holder to direct the optical beam onto the sample to modify an electric charge of the sample during the imaging or fabrication to improve spatial resolution of the imaging or fabrication.

### TECHNICAL FIELD

The present invention relates generally to apparatuses and methods for control or modification of surface charge, e.g., using shortwave electromagnetic radiation in nano-structuring or nano-imaging of materials, for example in ion beam and electron beam imaging and fabrication systems, including microscopy and fabrication tools where electrons and/or ions are used for surface imaging and/or fabrication (e.g., lithography, deposition, and milling), in particular at high resolutions, e.g., at sub-micrometer (μm), and nanometre (nm) scales.

### BACKGROUND

Ion-beam systems and electron-beam systems are increasingly used for high resolution imaging and fabrication (e.g., lithography, deposition, and milling), e.g., as imaging and fabrication is required at nanometre scales. Ion- and electron-beam imaging and fabrication tools include sources of electrons or positive ions, and these sources generate a stream of the electrons or ions directed to a surface of a sample, e.g., for imaging the surface, or for fabricating a pattern on the surface. Example tools include electron beam lithography (EBL) tools, ion beam lithography (IBL) tools, and focused ion beam (FIB) tools.

A limitation and impediment to high-resolution fabrication and imaging with ion beams and electron beams arises from charging of the surface of the sample due to the beam of the charged particles: the electrons or the ions. Because the surface charging is caused by irradiation with the charged particles, this charging can vary unpredictably across the surface over a duration of an irradiation process (an imaging or fabrication process). The surface charging can lead to spatial errors in a plane perpendicular to the beam of the charged particles, across the surface of the sample, thus effectively reducing the resolution of the imaging tools, or distorting patterns made using the fabrication tools. This reduction in the resolution of imaging and fabrication is due to a spatial distribution of charge across the surface, and this spatial distribution in the surface charge can steer a beam of charged particles significantly when the beam is focused down to a sub-micrometre scale, in particular down to a few nanometres. Thus the surface charging can cause a drift in images or fabricated patterns.

The surface charging effects caused by the charged particle beams may in some circumstances be reduced or ameliorated using a source of electrons (i.e., a second source of charged particles) known as an electron flood gun. The electron flood gun may create a more uniform charging on a patterned surface, thus reducing spatial dependencies of the surface charging caused by the beam of charged particles. The surface charging effects may also be addressed by coating the sample surface with a highly conductive layer that conducts the surface charges away from the surface as they are generated by the beam of charged particles; however, such a conductive coating requires modification of the original sample before the irradiation step. The conductive layer may be a metal coating or a polymeric coating (e.g., an “ESPACER” coating), and may require a conductive connection to large-volume metal tools grounded for charge removal (e.g., carbon tape connecting the sample surface to a conducting portion of the fabrication or imaging tool).

Existing methods of electron flood gun illumination and conductive layer coating are in some cases inacceptable e.g., because it is desirable to leave an initial pattern or geometry on the sample surface unaltered, or if a spatial precision of several nanometres is required. For example, when using a scanning electron microscope (SEM), a conductive coating of one to two nanometres of platinum/palladium may be required to remove the surface charge, and such a coating is expensive and may be incompatible with the sample.

It is desired to address or ameliorate one or more disadvantages or limitations associated with the prior art, or to at least provide a useful alternative.

### SUMMARY

In accordance with the present invention there is provided an apparatus for imaging or fabrication using charged particles, the apparatus including:

a charged particle source configured to generate a charged particle beam of ions or electrons:

a sample holder mounted relative to the charged particle source to hold a sample in the charged particle beam for the imaging or fabrication; and

an optical source system configured to generate an optical beam, wherein the optical source system is mounted relative to the sample holder to direct the optical beam onto the sample to modify an electric charge of the sample during the imaging or fabrication to improve spatial resolution of the imaging or fabrication.

The present invention also provides a sample holder for an ion-beam or electron-beam imaging or fabrication tool, including an optical source system delivering light in an optical beam, wherein the optical source system is mounted to the sample holder and aligned to project the optical beam on a sample, wherein the optical beam includes a wavelength selected to modify charger carriers in the sample formed by a charged particle beam of the tool.

The present invention also provides a method of manufacturing an apparatus for surface charge modification, the method including the step of:

mounting an optical source system in an apparatus for imaging or fabrication with a beam of charged particles,

wherein the optical source system is configured to generate an optical beam with a wavelength selected to modify a surface charge generated in the sample by the beam of charged particles to improve spatial resolution of the imaging or fabrication.

The present invention also provides a method of modifying an electronic charge of a sample irradiated by a beam of charged particles, the method including the step of:

illuminating a surface of the sample with an optical beam including one or more wavelengths selected to modify a surface charge generated by the beam of charged particles irradiating the surface to improve spatial resolution of imaging or fabrication with the beam of charged particles.

### BRIEF DESCRIPTION OF THE DRAWINGS

Preferred embodiments of the present invention are hereinafter described, by way of example only, with reference to the accompanying drawings, in which:

FIGS. 1A to 1E are schematic diagrams of different configurations of an apparatus for charged-beam imaging or fabrication;

FIG. 2 is a schematic diagram of a sample holder for the apparatus;

FIG. 3 is a schematic diagram of electron excitation to a free vacuum level from defects in a sample in the apparatus;

FIG. 4 is a schematic diagram of an example sample and holder in the apparatus;

FIG. 5A is an image of a pattern milled into titanium dioxide (TiO₂) using ion-beam lithography without surface charge control;

FIG. 5B is an image of a pattern milled into TiO₂ with surface charge control;

FIG. 6 is a precision map of milled holes in TiO₂ for different intensities (Iₙ) of a light source used for surface charge control;

FIG. 7 is a graph of averaged spatial error for a normalised use of the different intensities;

FIG. 8A is an image of a circle pattern design for milling on a TiO₂ surface;

FIG. 8B is a scanning electron microscope (SEM) image of the circle pattern from FIG. 8A milled using illumination with a wavelength of 250 nm at 80% current (including a scale bar of 1 micrometer);

FIG. 8C is an SEM image of the circle pattern from FIG. 8A milled using illumination with a wavelength of 270 nm at 80% current (including a scale bar of 1 micrometer);

FIG. 8D is an SEM image of the circle pattern from FIG. 8A milled using illumination light with a wavelength of 280 nm at 80% current (including a scale bar of 1 micrometer);

FIG. 8E is an SEM image of the circle pattern from FIG. 8A milled using illumination light with a wavelength of 290 nm at 80% current (including a scale bar of 1 micrometer);

FIG. 8F is an SEM image of the circle pattern from FIG. 8A milled without illumination (including a scale bar of 1 micrometer); and

FIG. 9 is an image of SEM circle patterns milled into aluminium foil under illumination from an optical source with a wavelength of 290 nanometres.

### DETAILED DESCRIPTION

### Apparatus

Described herein is an apparatus 100 configured: (i) to irradiate a sample with a charged particle beam (e.g., for imaging or fabrication using electrons and/or ions); and (ii) to illuminate the sample with light (i.e., photons) to control electronic charges in the sample—and in particular at or on the surface of the sample—generated by the charged beam. The control of the surface charges may be referred to as “surface charge compensation” or “modification”: the effects of the surface charges, which are strongly influenced by the charged beam, on the spatial resolution of the charged beam may simply be ameliorated or completely removed, rather than being completely controlled. The apparatus 100 may totally remove all excess charge created by charged particle beam, e.g., so nano-fabrication can happen without distortions. The control of surface charge can depend (1) on the wavelength of the light and (2) on the light's intensity, thus in some circumstances a rate of charge removal, can be controlled by changing the intensity of the incident light (e.g., see FIG. 7). By modifying the surface charge with an optical beam of the light, spatial resolution of imaging and fabrication with the charged beams may be improved. The apparatus 100 may allow performance of lithography at under 22 nm resolution, or fabrication of photonic crystals with sub-100-nm precision and an aspect ratio of 4 to 5 on dielectrics. The apparatus 100 may be used for fabrication of sub-20-nm features in the semiconductor industry. The apparatus 100 may be used for fabrication of photonic crystals with a full photonic bandgap in the visible range, which may be used to couple sunlight into solar calls more strongly. The apparatus 100 may be used for high-resolution ion fabrication in micro/nano-fluidic application, including maskless writing of gratings, hole arrays or other more complex patterns. The apparatus may be used to add material to the sample surface. The materials can be conductive (e.g., platinum, used by tools from FEI Company, or tungsten used by tools from Raith GmbH) or isolating (e.g., SiO2, or carbon (C) used by tools from Raith GmbH). The irradiation and illumination can be performed simultaneously or in succession with each other (e.g., repeatedly and in rapid succession) for some applications (e.g., switching the charged particle beam and the light source on and off in sequence at a high frequency.

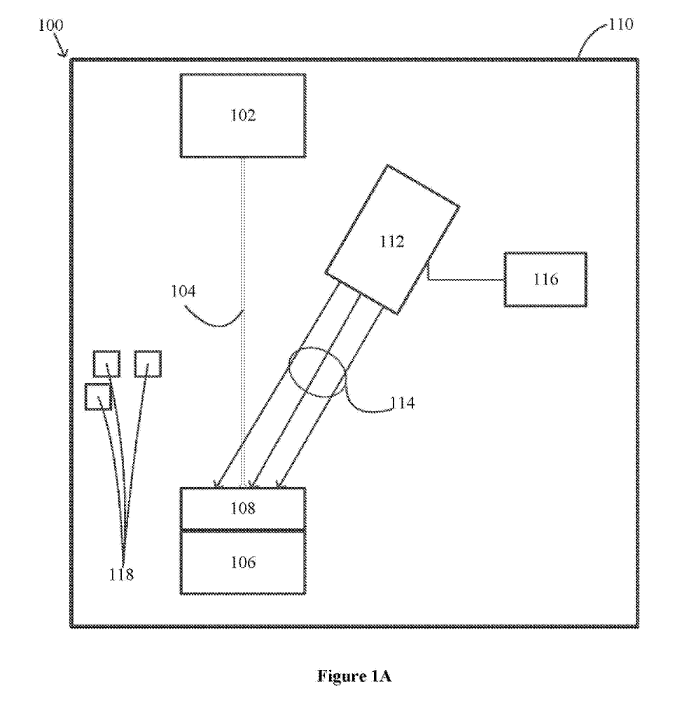

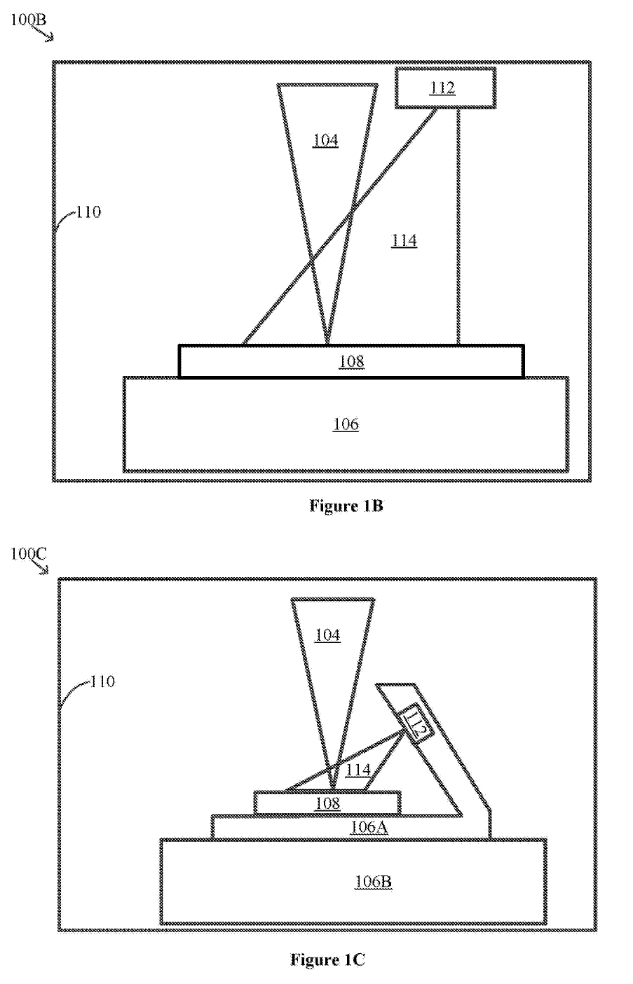

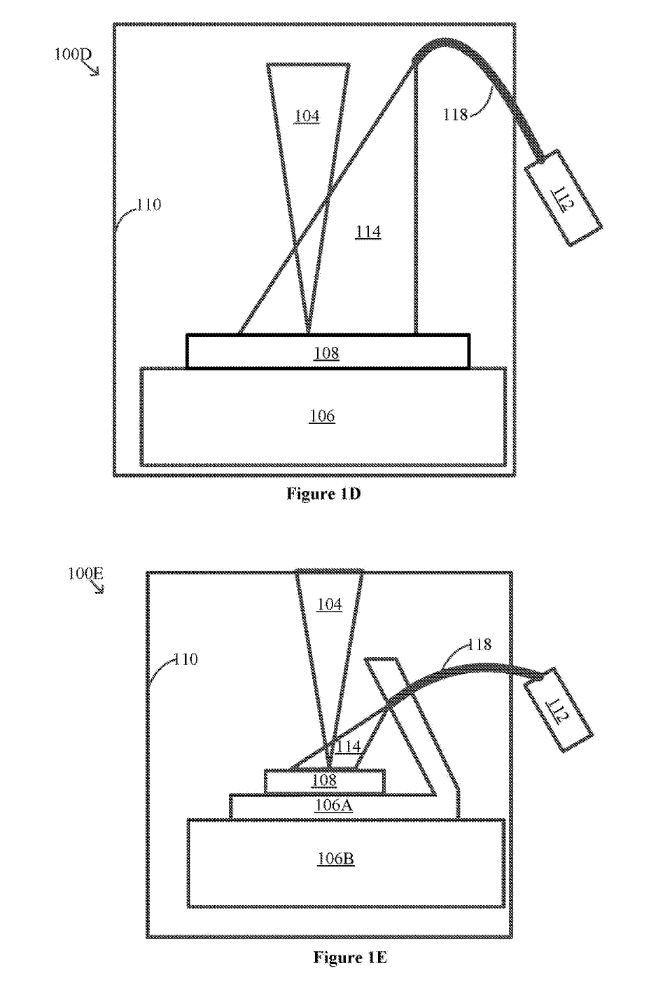

As shown in FIG. 1A, the apparatus 100 includes a charged particle source 102 (or a “gun”) for generating a charged particle beam 104.

The charged particle source 102 can be a source of electrons, thus generating a beam of electrons in the charged particle beam 104. Alternatively, the charged particle source 102 can be an ion source, thus generating a beam of ions in the charged particle beam 104. Example ions are gallium (Ga⁺) ions, helium (He⁺) ions, neon (Ne⁺) ions, xenon ions (Xe+), gold ions (Au+), silicon ions (Si+), and other ion sources.

The apparatus 100 includes a sample holder 106 configured to hold a sample 108 in position relative to the charged particle source 102 and the charged particle beam 104 so that the charged particle beam 104 can be used to fabricate or mill the surface of the sample 108, or image the surface of the sample 108, using commercially available fabrication or imaging components in the apparatus 100, and in accordance with existing fabrication or imaging procedures. The sample holder 106 can include a plurality of mechanically connected components, for example: a sample mount for securing the sample 108 in position; and a stage (e.g., with actuators) for moving the sample 108 relative to the charged particle beam 104. The sample 108 may be a dielectric slab with a thickness of 50 nm (e.g., for a silicon nitride membrane) to 2 millimetre (mm) (e.g., for soda lime glass), but the sample 108 can be any height as long as it fits under the charged particle source 102 and the sample surface can be illuminated by an optical beam 114 described hereinafter to modify the surface charge. A bulk material of the sample 108 can be TiO₂, soda-lime glass, borosilicate (BK7) glass, diamond, sapphire, or aluminium oxide (Al₂O₃).

The sample material can be a metal.

The charged particle source 102 and the sample holder 106 are mounted in a casing 110 of the apparatus 100. The sample holder 106 can include a kapton tape spacer, which may electrically isolate of the surface of the sample 108 from other portions of the apparatus 100, e.g., the casing 110.

The casing 110, the charged particle source 102 and the sample holder 106 can be components of commercially available imaging and fabrication tools. Example tools include electron beam lithography (EBL) tools, ion beam lithography (IBL) tools, and focused ion beam (FIB) tools. A particular example is the “IonLiNE” apparatus from Raith GmbH. The apparatus 100 may include a vacuum chamber around the sample 108 and sample holder 106, and an optical source system may be mounted or installed in the vacuum chamber. The apparatus 100 can be configured for nano-scale operation through the inclusion of actuators to control a spot (referred to as the “ion beam spot”) of the charged particle beam 104 on the surface of the sample 108 with nanometre precision.

The apparatus 100 includes, mounted in or to the casing 110, the optical source system including an optical source 112 which generates (i.e., provides) the light for the optical beam 114 including optical wavelengths (e.g., ultraviolet (UV)). The optical source 112 can be a lamp, a laser or a light-emitting diode (LED). The optical source 112 can be a semiconductor diode-based source, e.g., an LED or diode laser. The optical source 112 can be a coherent light source (e.g., a laser) or an incoherent light source (e.g., an LED). An example optical source can be a commercially available deep-UV LED operating at short electromagnetic radiation wavelengths of about 240 to 280 nanometres. Example 240 nm LEDs are available in the market at the moment; however, 200 nm or 150 nm LEDs may be preferable, e.g., for particular sample materials. The optical source system may be referred to as an optical “anti-charging gun”, e.g., a short-wavelength electromagnetic-radiation anti-charging gun.

The optical source 112 may be sufficiently small to fit inside the casing 110 of the apparatus 100, requiring only a power source, e.g., for electrical power, or a connection to a power source. The optical source 112 can be mounted on a gun nozzle of the charged-particle source 102. The optical source 112 can be controlled to operate simultaneously with the charged particle source 102: i.e., the apparatus is configured (by relative mounting and control of the optical source system and the charged particle source 102) such that the optical source system can direct the optical beam 114 onto the sample at the same time as the charge particle source 102 generates the charged particle beam 104 and directs the charged particle beam 104 onto the sample 108; alternatively or additionally, the optical source 112 can be controlled to be operate successively or in sequence with the charged particle source 102. The optical beam 114 may be a focussed or directed beam provided (i.e., directed) by micro-optical/optical guiding components, e.g., (optical filters, mirrors, lenses, waveguides and optical fibres in the optical source system), and/or a plurality of focussed or directed different wavelength beams coincident on the sample 108, and/or a diffuse area of light directed onto the sample 108. The optical guiding components may deliver the light to form the optical beam 114, e.g., through or in the casing 110. For example, optical fibres can guide light from LEDs to form the optical beam 114. The optical guiding components may include collimators to improve angular control of the optical beam 114. The guiding optics for the optical beam 114 may be inside or exterior to the casing 110. The fibres may be UV fibres for guiding wavelengths. The final emitting optical guiding component (e.g., emitting end of a fibre) is optically connected to the optical source 112 (which can be outside the casing 110) and delivers the light to provide and form the optical beam 114 (i.e., directs the optical beam 114).

The optical source system (include the optical source 112 and any optical guiding components) is mounted relative to the sample holder 106 in the casing 110 to direct the optical beam 114 onto the sample to create an optical spot that overlaps the ion beam spot formed where the charged particle beam 104 strikes the sample surface. A distance between the emitting end of the optical source system and the sample 108, and an angle of incidence of the optical beam 114 on the sample 108, can be selected using mounting positions of the optical source system and the sample holder 106 in the casing 110: a shorter distance between the optical source 112 and the sample 108 may be more efficient for charge modification. The optical source 112 and the sample 108 can be mounted relative to each other such that the incidence angle of the optical beam 114 on the sample 108 is equal to or close to Brewster's angle to minimise reflection of the optical beam 114 from the surface of the sample 108. The charged particle source 102 and the optical system are mounted/arranged so as to not interfere with, occlude or block each other's beams 104, 114. Furthermore, the photons in the optical beam 114 do not substantially deflect the particles in the charged particle beam 104.

The optical source 112, or the final component of the guiding optics, is mounted in the casing 110 relative to the sample holder 106 and the charged particle source 102 so as to direct the optical beam 114 onto the surface of the sample 108 during irradiation of the sample 108 with the charged particle beam 104 so that the optical beam 114 modifies charges on and in the sample 108 as they are generated by the charged particle beam 104 (e.g., photons in the optical beam 114 may act to eject electrons from the sample surface).

The optical beam 114 may include light (i.e., photons), generated by the optical source 112, at wavelengths that are suitable to eject charged particles from the surface of the sample 108, thus causing removal of electrons from the sample 108 to a free state (e.g., a free vacuum state) in the apparatus 100. The wavelengths of the light in the optical beam 114 may be selected or controlled based on determined material properties of the sample 108. The light wavelengths can be short enough to cause electron transfer from the surface to the free vacuum state. Ultraviolet (UV) wavelengths can be used, including deep UV wavelengths with energies of about 5 electron Volts (eV) or more. For example, for a glass sample or a diamond sample, illumination with 250-nm or 260-nm wavelength light may release electrons trapped in defect states created during irradiation with a Ga⁺ beam. A short illumination wavelength may in general be more efficient for charge modification.

As shown in FIGS. 1B to 1E, the apparatus 100 can have different configurations with different mounting locations of the optical source 112 relative to the casing 110. In a gun-mounted configuration 100B, as shown in FIG. 1B, the optical source 112 is mounted adjacent or on the charged particle source 102 so that the optical beam 114 is incident onto the sample 108 at an incidence angle of about 90 degrees to the sample surface. In a holder-mounted configuration 100C, as shown in FIG. 1C, the optical source 112 is mounted in or on the holder 106 (which can include a two-part holder 106A and a stage 106B) so that the optical beam 114 is incident onto the sample 108 at an incidence angle of about 30 to 60 degrees to the sample surface. In a guide-on-gun configuration 100D, as shown in FIG. 1D, an optical guide 118 (e.g., including an optical fibre and coupling components) is connected to the optical source 112 (which may be outside the casing 110), and the optical guide 118 is mounted adjacent or on the charged particle source 102 so that the optical beam 114 is incident onto the sample 108 at an incidence angle of about 90 degrees to the sample surface. In a guide-on-holder configuration 100E, as shown in FIG. 1E, the optical guide 118 is connected to the optical source 112 (which may be outside the casing 110), and the optical guide 118 is mounted in or on the holder 106 (which can include a two-part holder 106A and a stage 106B) so that the optical beam 114 is incident onto the sample 108 at an incidence angle of about 30 to 60 degrees to the sample surface.

As shown in FIG. 2, the end of the optical source system—for example the optical source 112 in the form of an array of LEDs—can be mounted to the sample holder 106, e.g., using a two-part sample holder 202 having a first face 204 with a sample holder 206 and a second face 208, visible from the first face 204, with a location mount 210 for the optical source 112. The second face 208 can be on a tilted plane overlooking the sample location 206, e.g., at an angle of about 60 degrees. For example sample holder, with an incidence angle of about 60 degrees for the optical beam 114, a distance between the optical source 112 and the location of the sample 108 can be about 9 mm.

The optical source system is mounted and controlled in the apparatus 100 so that it can be used simultaneously with the charged particle source 102. The locations and orientations of the optical source 112 and the optical source system in the casing 110 may differ for different commercially-available imaging and fabrication tools. For example, in Raith GmbH's EBL and IBL tools, the optical source 112 can be above the sample 108. In another example, in a dual-beam FIB tool, e.g., from Hitachi, JEOL USA, Inc. or FEI Company, the optical source 112 can be mounted to deliver the optical beam 114 at a slanted angle to the sample 108.

The apparatus 100 includes a controller 116 connected to the optical source system (in particular to the optical source 112, and to any active components of the guiding components, e.g., active mirrors, active filters, etc.) to control the optical power (and thus the intensity) of the optical beam 114, and/or to control the optical wavelength(s) in the optical beam 114 (and in some cases to control the location of the optical spot relative to the sample 108). The controller 116 can include one or more commercially available electronic controllers for light sources and active optical components. The controller 116 can control or steer the location of the optical spot from the optical beam 114 on the sample surface, e.g., for spatial control or modification of the surface charge e.g., if the surface charge has been delivered to different locations on the surface by the charged particle beam 104. The beam steering can be performed using the guiding components, e.g., mirrors, or by moving the optical source 112, e.g., a LED. In general, compared to the size and location of the ion beam spot, the optical spot is wide-spread and stationary.

The optical source 112 may generate a plurality of different optical wavelengths in one or more sub-beams of the optical beam 114. The optical source 112 may include a plurality of different sources controlled by the controller 116 (which may include a plurality of sub-controllers). The plurality of different sources may be arranged in different locations in the casing 110, may operate at respective different optical wavelengths, and may generate the different optical sub-beams (which may be collinear or may be non-collinear) in the optical beam 114. Having a plurality of different optical wavelengths in the optical beam 114 can allow the apparatus 100 to discharge electrons trapped at different energy levels in the sample 108, e.g., arising due to different materials in the sample, and/or different charged particles in the charged particle beam 104, and/or different defects and trapping effects caused by the charged particle beam 104.

The apparatus 100 may include a plurality of electrodes 118 mounted in the casing 110, e.g., close to and above the surface of the sample 108, and not occluding the charged particle beam 104 or the optical beam 114, to gather or collect the electrons freed by the optical beam 114. The electrodes 118 may be positively electrically biased by an direct-current electronic controller.

### Methods

A method of manufacturing the apparatus 100 includes at least the following steps:
mounting the optical system (including the optical source 112 and any of the optical guiding components that guide the optical beam 114) in or to the casing 110 of the fabrication tool or the imaging tool with the charged particle source 102 and the sample holder 106 such that the optical source system does not occlude or block the charged particle beam 104, and to direct the optical beam 114 onto the sample 108 in an area (referred to as the “optical spot”) that at least covers the incident area of the particle beam 104 (and may be significantly larger), and optionally at or close to the Brewster's angle (to make the charge modification effect more efficient; the angle may also be chosen to lie between 89.9 degrees (when it is mounted close to gun) and 0.1 degrees (when it is mounted on sample holder), which may include mounting and aligning the optical guiding components (e.g., mirrors, lenses and optical fibres) in or to the casing 110 to direct the optical beam 114—so that the optical spot can illuminate a sufficient area of the sample surface to modify electronic charges that would adversely affect the location of the ion beam spot;
configuring the optical source 112 to include one or more wavelengths in the optical beam 114 to modify the surface charge (e.g., by freeing electrons from the material of the sample surface);
configuring the optical source 112 to provide an intensity or a range of intensities in the optical beam 114 to provide a sufficient rate of surface charge modification for the particular fabrication or imaging tool (e.g., taking into account the rate of charged particles in the particle beam 104, the spot size of the particle beam 104 on the surface of the sample 108, etc.); and
electronically connecting the controller 116 to the optical source 112 to allow electronic communication between the controller 116 and the optical source 112.

A method of modifying an electronic charge of a sample irradiated by a beam of charged particles using the apparatus 100 includes at least the following steps:
irradiating the ion beam spot (an area) on the surface of the sample 108 mounted on the sample holder 106 with the charged particle beam 104 to image the surface or to mill/fabricate the surface; and
illuminating the optical spot (an area) on the surface of the sample 108 with the optical beam 114 to modify the charge distribution in and/or on the sample (e.g., by removing electrons from the surface) at least within the optical spot, wherein the optical spot overlaps with the ion beam spot (e.g., the optical spot can completely surround and overlap with the ion beam spot), to improve spatial resolution of the imaging or fabrication with the beam of charged particles.

The irradiating step and the illuminating step can be performed simultaneously, or can be performed in succession.

The charge modification method can include the steps of controlling the optical intensity, optical wavelength, and/or location of the optical spot on the sample 108 to modify surface charges generated by the charged particle beam 104, e.g., by sweeping the optical spot across the surface in a pattern that follows the ion beam spot. In other cases, the source 112 is stationary, and the optical beam 114 covers a much larger area than the area covered during fabrication or imaging with the particle beam 104 on the sample 108.

### Examples

In experimental examples, focused ion fabrication was carried out using Raith's IonLiNE to nano-pattern surfaces of different materials. A nano-hole pattern arranged into a cross-shape, with separation between the fabrication sites of about 1 μm, was used to test charging-induced distortions. The typical ion fabrication current was about 20 pA for a 40 μm aperture, and an ion beam was focused to a 20-nm spot on the sample's surface at a 35 kV voltage.

The experimental samples were dielectric slabs of about 50 nm to 2 mm thickness. The materials tested in the discharging experiments exhibited strong charging effects, including: TiO₂, soda-lime and borosilicate (BK7) glasses, chemical vapour deposition (CVD) diamond, Al₂O₃, Si₃N₄, and LiNbO₃. A kapton spacer 402 was used between an example stage 404 and example samples 406 to maximise charge modification by the illumination compared to other effects (e.g., charge escaping through the sample-sample holder interface) during the ion fabrication, as shown in FIG. 4. All previously mentioned materials were tested for charging on kapton isolation pads with and without UV illumination.

Example deep-UV LEDs emitting at about 250-nm to 290-nm wavelengths were used in an example LED anti-charging gun. The example LEDs were mounted on a tilted plane overlooking the sample at about 60° angle of incidence with a LED-to-irradiation spot distance of about 9 mm. The angle was chosen to be close to Brewster's angle in order to minimize reflection. The emission power of the LED was proportional to the driving current, which was from 0 to 20 mA (100%).

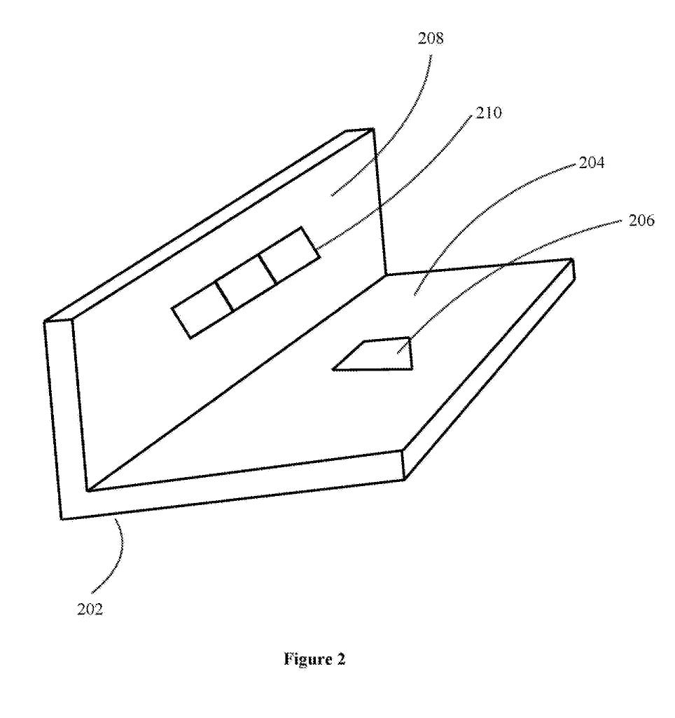

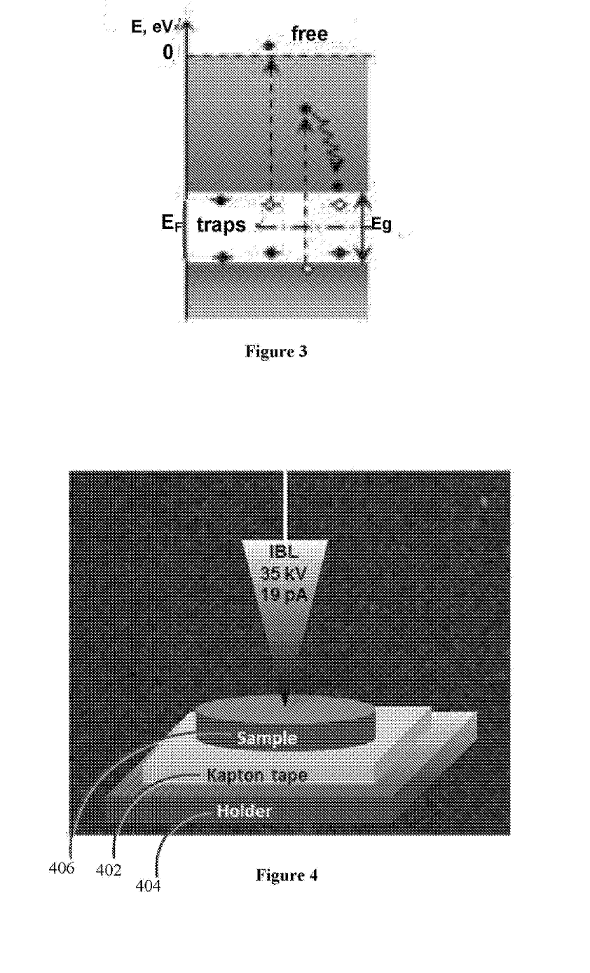

The electrons may be freed from the example sample surface as shown in FIG. 3: an electron is excited to a free vacuum level from traps and defects induced by the ion fabrication. The bandgap is E_{g} and the Fermi level is E_{F}. The energy of vacuum (free) level for the electron is 0 eV. Possible UV-light induced transitions are shown by vertical arrows in FIG. 3.

FIGS. 5A and 5B show IBL images of a pattern on TiO₂ without (SA) and with (SB) compensation of charging. Ion beam imaging was carried out by the Raith IonLiNE.

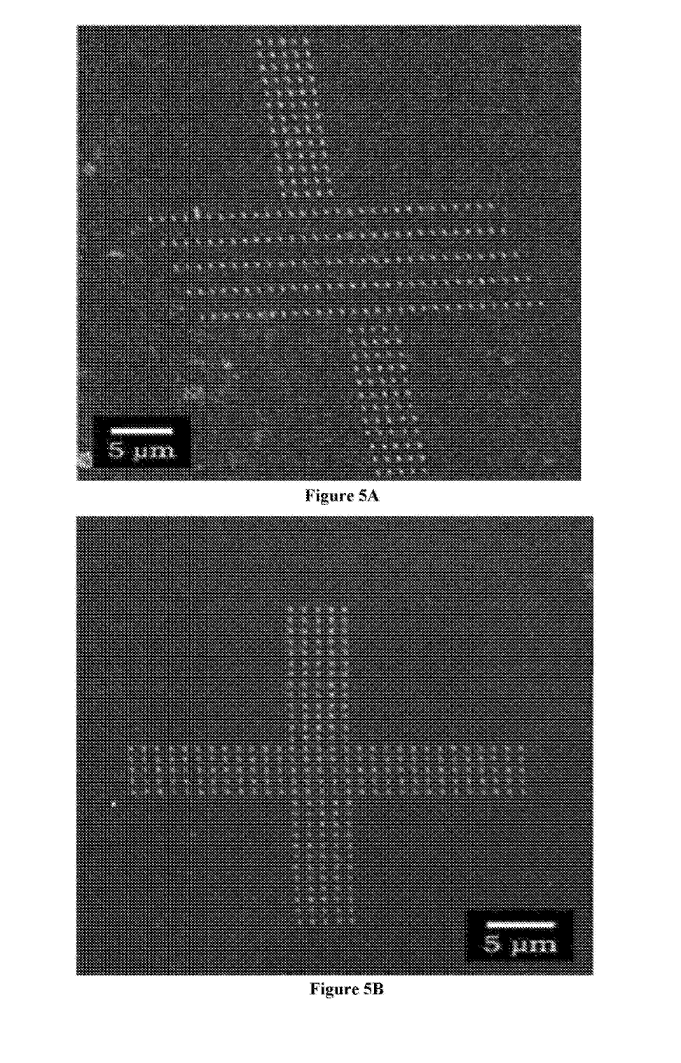

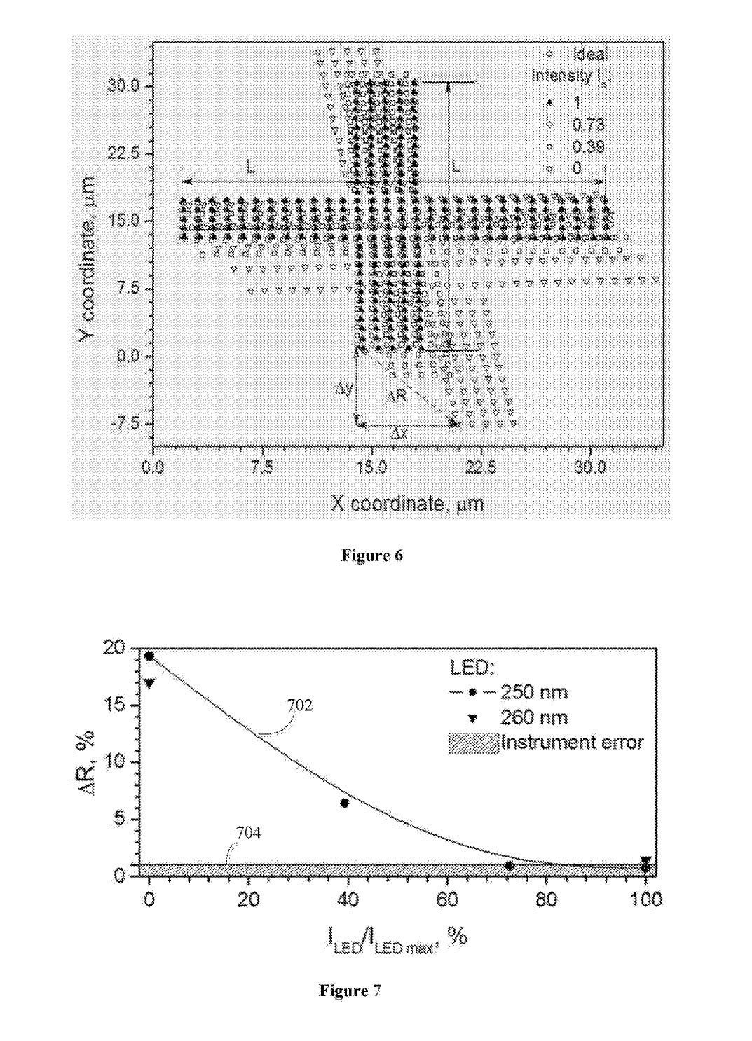

FIG. 6 shows a position map of milled nano-holes on the surface of TiO₂ at different intensities of LED anti-charging gun illumination. The patterns were numerically overlayed at the top-left corner of the central square feature. The departure of the most far-away corner points was compared with the designed positions by calculating the departure parameter ΔR=Δx²+Δy². The first writing point was the one in the most bottom-left corner of the pattern. The charging effects can be evaluated by overlaying the patterns at the staring fabrication point; however, then the errors for the first fabricated holes are the largest and are not representative for the entire pattern. The fidelity of surface patterning is quantified by plotting ΔR α Iₙ as a line 702 where the normalized intensity of LED is Iₙ=I_{LED}/I_{LEDmax} with I_{LEDmax} being the intensity of LED at the maximum 20 mA current, as shown in FIG. 7. Here, the average value of ΔR was normalized to the length of the pattern L (see, FIG. 6) for the 8 corner points of the pattern. Almost perfect pattern geometry (as designed) was retrieved when the LED anti-charging gun was working above 80% of its intensity. After fabrication, the anti-charging gun was switched off, and imaging was carried out by IBL at low current (without the LED anti-charging gun) and some charging and pattern distortions were still present (shown as a horizontal line in FIG. 7). Scanning electron microscopy (SEM) was used to characterize the quality of the fabrication and modification of the charging. When the charging was strong during ion fabrication, the distortions were large, unpredictable, and took place all over the entire region where fabrication was carried out (as shown in FIG. 5A).

The anti-charging action of the deep UV photons (with energies of about 5 eV) may be explained by reference to the photo effect of electrons trapped in traps and defects induced by heavy Ga-ions during fabrication. The positive charge ions may have created avalanches of secondary electrons and defects in pre-surface regions of the sample (see FIG. 3). The acceleration voltage of the Ga-ions was up to 35 keV and a strong generation of defects was expected. Wavelengths of 250 and 260 nm showed similar performances (see FIG. 7), and had similar emitting surface geometries and powers on the surface of the TiO₂ and the diamond. The example LEDs did not have focusing optics. As illumination flux was increased, the error of the fabrication decreased (see FIG. 7). At 80% of the maximum current, full compensation of the distortions was achieved.

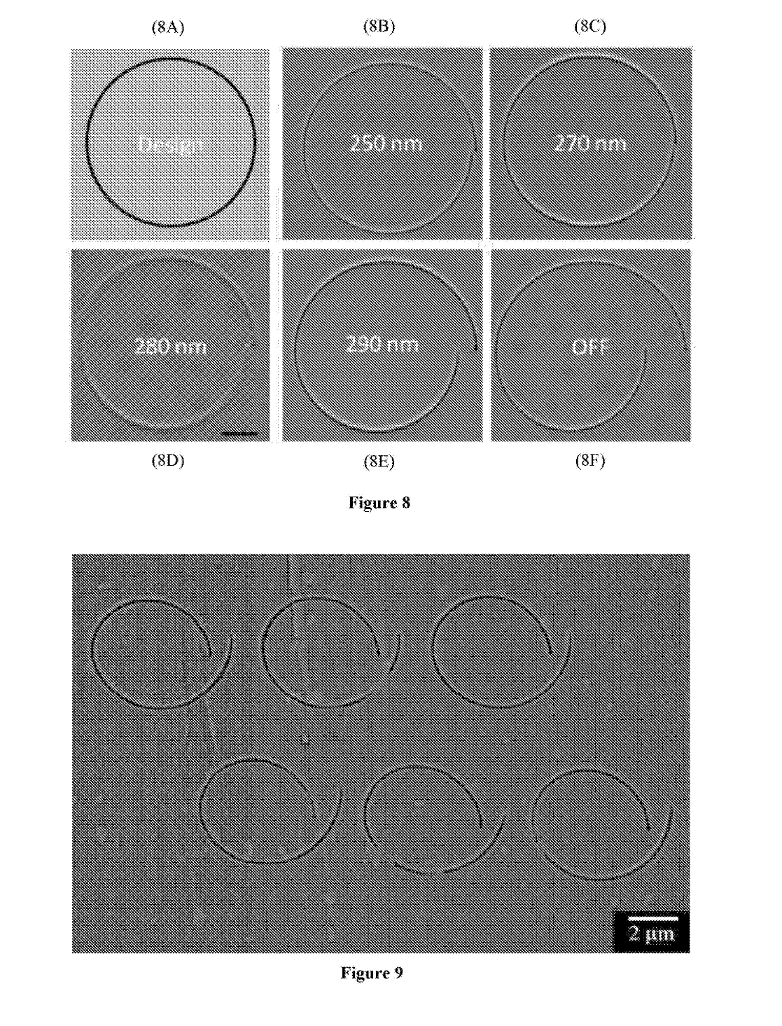

Several substrates were used with strong charging: BK7 glass, diamond, Si₃N₄, TiO₂ and Al₂O₃. The electron work functions for the materials were: Al₂O₃4.3-5.5 eV, SiO₂ 4.4-5.5 eV, Si₃N₄2.6 eV, TiO₂ 4.9-5.2 eV. The effect of charge modification was present for the shortest tested 250 nm wavelength illumination. The known electron work functions of different materials became less relevant in quantifying the discharging effect from ion-structured surfaces since the defects introduced by ion damage could have different energy locations close to the valence or conduction bands (see FIG. 3). Consequently, a different UV wavelength may be required for electron removal from the surface (i.e., not from the Fermi level as would be the case for an untreated material). Table I shows a qualitative summary of the charge modification of the sample at several experimental LED wavelengths and for several materials. Marker (+) corresponds to the case where start and end points are separated less than the width of the milled groove, and (−) when the separation is larger. A O-circle was milled on the surface under illumination corresponding to a 80% current. If charging was present, the start and end points did not match. At the longest wavelength of 290 nm (4.27 eV), only partial charge modification was observed in TiO₂ (work function about 5.0 eV). FIG. 8 shows data for TiO₂ (Table I). As the wavelength was increased, separation between the start and end points increased, and the UV illumination may have become less effective in terms of charge modification when λ>290 nm.

TABLE 1

| | λ = | λ = | λ = | λ = |
|---|---|---|---|---|
| | 250 nm | 270 nm | 280 nm | 290 nm |
| TiO2 (4.9 to 5.2 eV) | + | + | + | +/− |
| Al2O3 (4.3 to 5.5 eV) | + | +/− | +/− | − |
| Al (4.08 eV) | + | +/− | +/− | − |

Ga-ions beams can be capable of milling through different materials, dielectrics and metals, and can work on complex 3D nano-landscapes, e.g., it may be desirable to ion-structure a metal on a dielectric, in which case charging of metals may become an issue. FIG. 9 shows Ga-fabrication of Al foil placed on an isolating kapton film under a 290 nm LED illumination, which is close to the work function of Al (about 4.1 eV). Strong distortions were observed for the O-shape, indicating a poor charge modification by a longer wavelength UV illumination. Under the shorter wavelengths, there were no discernable shape distortions (Table I). For Ni (5.01 eV), there was no discernable charge modification for the wavelengths λₑₓ>250 nm (4.96 eV), indicating a possible influence of the photo-effect in excess charge removal from electrically isolated metals.

### INTERPRETATION

Many modifications will be apparent to those skilled in the art without departing from the scope of the present invention.

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

### RELATED APPLICATIONS

The present application is related to Australian provisional patent application no. 2013903073 filed on 15 Aug. 2013, the original specification of which is hereby incorporated in its entirety by reference herein.

1. An apparatus for imaging or fabrication using charged particles, the apparatus including:
a charged particle source configured to generate a charged particle beam of ions or electrons;
a sample holder mounted relative to the charged particle source to hold a sample in the charged particle beam for the imaging or fabrication; and
an optical source system configured to generate an optical beam, wherein the optical source system is mounted relative to the sample holder to direct the optical beam onto the sample to modify an electric charge of the sample during the imaging or fabrication to improve spatial resolution of the imaging or fabrication.

2. The apparatus of claim 1, wherein the apparatus is configured such that the optical source system can direct the optical beam onto the sample at the same time as the charge particle source generates the charged particle beam and directs the charged particle beam onto the sample.

3. The apparatus of claim 1 or 2, wherein the optical source system includes an optical source with a light source, including one or more light emitting diodes (LEDs) and/or laser diodes, and wherein the optical source system includes optical guiding components to guide the optical beam, e.g., one or more optical fibres.

4. The apparatus of any one of claims 1 to 3, wherein the optical source system is configured to generate the optical beam with deep ultra-violet (UV) wavelengths.

5. The apparatus of any one of claims 1 to 4, including a controller connected to the optical source system to control a wavelength of the optical beam, and/or a location of an optical spot illuminated by the optical beam on the sample.

6. The apparatus of any one of claims 1 to 5, wherein the charged particle source is a source of ions, and the charged particle beam includes the ions.

7. The apparatus of any one of claims 1 to 6, including actuators connected to the charged particle source and/or the sample holder configured to move the sample relative to the charged particle beam to provide nanometer-scale fabrication or imaging.

8. The apparatus of any one of claims 1 to 7, including electrodes mounted in the apparatus and electrically charged to capture electrons ejected from the sample by the optical beam.

9. The apparatus of any one of claims 1 to 8, wherein the optical source system is configured to generate the optical beam to remove electrons from the sample.

10. A sample holder for an ion-beam or electron-beam imaging or fabrication tool, including an optical source system delivering light in an optical beam, wherein the optical source system is mounted to the sample holder and aligned to project the optical beam on a sample, wherein the optical beam includes a wavelength selected to modify charge carriers in the sample formed by a charged particle beam of the tool.

11. A method of manufacturing an apparatus for surface charge modification, the method including the step of:
mounting an optical source system in an apparatus for imaging or fabrication with a beam of charged particles,
wherein the optical source system is configured to generate an optical beam with a wavelength selected to modify a charge generated in the sample by the beam of charged particles to improve spatial resolution of the imaging or fabrication.

12. The method of claim 11, wherein the charged particles are ions.

13. A method of modifying an electronic charge of a sample irradiated by a beam of charged particles, the method including the step of:
illuminating a surface of the sample with an optical beam including one or more wavelengths selected to modify a surface charge generated by the beam of charged particles irradiating the surface to improve spatial resolution of imaging or fabrication with the beam of charged particles.

14. The method of claim 13, wherein the charged particles are ions.

15. The method of claim 13 or 14, including illuminating the surface of the sample with the optical beam simultaneously with irradiating the surface with the charged particles.
